(19) United States
(12) Patent Application Publication
(10) Pub. No.: US 2024/0419088 A1
(43) Pub. Date: Dec. 19, 2024

(54) METHOD AND APPARATUS FOR LITHOGRAPHIC IMAGING

(71) Applicant: ASML NETHERLANDS B.V., Veldhoven (NL)

(72) Inventors: Akshay Dipakkumar HARLALKA, Norwalk, CT (US); Muthukumaran LOGANATHAN, Norwalk, CT (US); Eric Scott SLOAN, Norwalk, CT (US); Bill CHANG, Norwalk, CT (US); Santiago E. DEL PUERTO, Myrtle Beach, SC (US); Daniel Nathan BURBANK, Ridgefield, CT (US); Brandon Adam EVANS, Norwalk, CT (US); Venkata Siva Chaithanya CHILLARA, Norwalk, CT (US); Joseph George WIHBEY, III, Stamford, CT (US)

(73) Assignee: ASML NETHERLANDS B.V., Veldhoven (NL)

(21) Appl. No.: 18/719,902

(22) PCT Filed: Nov. 25, 2022
(86) PCT No.: PCT/EP2022/083370

§ 371 Date: Jun. 14, 2024

Related U.S. Application Data
(60) Provisional application No. 63/332,800, filed on Apr. 20, 2022.
(60) Provisional application No. 63/292,793, filed on Dec. 22, 2021.

(51) Int. Cl. G03F 7/00

(52) U.S. Cl. CPC G03F 7/70725; G03F 7/707; G03F 7/70766

(57) ABSTRACT

Systems, methods, and computer programs for providing a force opposed to inertial forces present on a patterning device during imaging operations of a photolithographic system include a means for providing coarse positioning of a pusher in combination with a short-stroke actuator and pushing tip configured to engage an edge of the patterning device. In an embodiment, the coarse positioning is provided by providing a guide along which the short-stroke actuator may be translated, and a locking mechanism is configured to selectively hold the actuator in place relative to the patterning device. In an embodiment, the coarse positioning is provided by a long-stroke actuator, for example an eccentric linear drive actuator.

### CROSS-REFERENCE TO RELATED APPLICATIONS

This application claims priority of (1) U.S. Provisional Patent Application No. 63/292,793, which was filed on Dec. 22, 2021, and (2) U.S. Provisional Patent Application No. 63/332,800, which was filed on Apr. 20, 2022, both of which are incorporated herein in their entirety by reference.

### TECHNICAL FIELD

The description herein relates generally to improving and optimizing lithography processes. More particularly, the disclosure includes apparatus, methods, and computer programs for helping stabilize a patterning device during accelerating movements of the patterning device holder.

### BACKGROUND

A lithographic projection apparatus can be used, for example, in the manufacture of integrated circuits (ICs). In such a case, a patterning device (e.g., a mask) may contain or provide a pattern corresponding to an individual layer of the IC (“design layout”), and this pattern can be transferred onto a target portion (e.g. comprising one or more dies) on a substrate (e.g., silicon wafer) that has been coated with a layer of radiation-sensitive material (“resist”), by methods such as irradiating the target portion through the pattern on the patterning device. In general, a single substrate contains a plurality of adjacent target portions to which the pattern is transferred successively by the lithographic projection apparatus, one target portion at a time. In one type of lithographic projection apparatuses, the pattern on the entire patterning device is transferred onto one target portion in one go; such an apparatus may also be referred to as a stepper. In an alternative apparatus, a step-and-scan apparatus can cause a projection beam to scan over the patterning device in a given reference direction (the “scanning” direction) while synchronously moving the substrate parallel or anti-parallel to this reference direction. Different portions of the pattern on the patterning device are transferred to one target portion progressively. Since, in general, the lithographic projection apparatus will have a reduction ratio M (e.g., 4), the speed F at which the substrate is moved will be 1/M times that at which the projection beam scans the patterning device. More information with regard to lithographic devices can be found in, for example, U.S. Pat. No. 6,046,792, incorporated herein by reference.

Prior to transferring the pattern from the patterning device to the substrate, the substrate may undergo various procedures, such as priming, resist coating and a soft bake. After exposure, the substrate may be subjected to other procedures (“post-exposure procedures”), such as a post-exposure bake (PEB), development, a hard bake and measurement/inspection of the transferred pattern. This array of procedures is used as a basis to make an individual layer of a device, e.g., an IC. The substrate may then undergo various processes such as etching, ion-implantation (doping), metallization, oxidation, chemo-mechanical polishing, etc., all intended to finish off the individual layer of the device. If several layers are required in the device, then the whole procedure, or a variant thereof, is repeated for each layer. Eventually, a device will be present in each target portion on the substrate. These devices are then separated from one another by a technique such as dicing or sawing, whence the individual devices can be mounted on a carrier, connected to pins, etc.

Thus, manufacturing devices, such as semiconductor devices, typically involves processing a substrate (e.g., a semiconductor wafer) using a number of fabrication processes to form various features and multiple layers of the devices. Such layers and features are typically manufactured and processed using, e.g., deposition, lithography, etch, chemical-mechanical polishing, and ion implantation. Multiple devices may be fabricated on a plurality of dies on a substrate and then separated into individual devices. This device manufacturing process may be considered a patterning process. A patterning process involves a patterning step, such as optical and/or nanoimprint lithography using a patterning device in a lithographic apparatus, to transfer a pattern on the patterning device to a substrate and typically, but optionally, involves one or more related pattern processing steps, such as resist development by a development apparatus, baking of the substrate using a bake tool, etching using the pattern using an etch apparatus, etc.

As noted, lithography is a central step in the manufacturing of device such as ICs, where patterns formed on substrates define functional elements of the devices, such as microprocessors, memory chips, etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend referred to as “Moore's law.” At the current state of technology, layers of devices are manufactured using lithographic projection apparatuses that project a design layout onto a substrate using illumination from a deep-ultraviolet illumination source, creating individual functional elements having dimensions well below 100 nm, i.e. less than half the wavelength of the radiation from the illumination source (e.g., a 193 nm illumination source).

This process in which features with dimensions smaller than the classical resolution limit of a lithographic projection apparatus are printed, is can be referred to as low-k1 lithography, according to the resolution formula CD=k1×λ/NA, where λ is the wavelength of radiation employed (e.g., 248 nm or 193 nm), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a designer in order to achieve particular electrical functionality and performance. To overcome these difficulties, sophisticated fine-tuning steps are applied to the lithographic projection apparatus, the design layout, or the patterning device. These include, for example, but not limited to, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. The term “projection optics” may also include components operating according to any of these design types for directing, shaping or controlling the projection beam of radiation, collectively or singularly. The term “projection optics” may include any optical component in the lithographic projection apparatus, no matter where the optical component is located on an optical path of the lithographic projection apparatus. Projection optics may include optical components for shaping, adjusting and/or projecting radiation from the source before the radiation passes the patterning device, and/or optical components for shaping, adjusting and/or projecting the radiation after the radiation passes the patterning device. The projection optics generally exclude the source and the patterning device.

### SUMMARY

Systems, methods, and computer programs for reducing movement of a patterning device on a patterning device holder during acceleration of the patterning device holder.

In an embodiment, a patterning device holder includes a chuck configured to releasably hold and support the patterning device. It further includes an actuator configured to apply a holding force to an edge of the patterning device, the holding force being opposed to an inertial force on the patterning device in response to acceleration of the patterning device holder, the actuator including a fine-stroke portion and a tip portion, wherein the actuator is slidingly mounted on a guide. A locking mechanism is configured to selectively hold the actuator in place relative to the patterning device, and the actuator is configured to controllably position the tip portion to a pushing position in which the tip portion is engaged with the edge of the patterning device and to a disengaged position in which the tip portion is not engaged with the edge of the patterning device, and wherein the actuator is movable along the guide from the disengaged position to the pushing position. In an embodiment, the motion of the actuator is in response to inertial forces due to acceleration of the patterning device holder.

In an embodiment, a patterning device transport system for use in holding and moving a patterning device in a lithographic imaging apparatus, includes a patterning device holder, the patterning device holder including a chuck configured to releasably hold and support the patterning device. It further includes an actuator configured to apply a holding force to an edge of the patterning device, the holding force being opposed to an inertial force on the patterning device in response to acceleration of the patterning device holder. The actuator including a long-stroke actuator portion including a linear eccentric drive, a brake configured to prevent parasitic forces from moving the long-stroke actuator portion, a short-stroke actuator portion, connected to the long-stroke actuator portion, and

a tip portion, wherein the tip portion is configured to apply the holding force to the edge of the patterning device, the long-stroke actuator portion has a longer travel stroke than a travel stroke of the short-stroke actuator portion and the short-stroke actuator portion has a greater degree of precision than a degree of precision of the long-stroke actuator portion. The long-stroke actuator portion is configured to controllably move the tip portion towards and away from the edge of the patterning device such that the tip is configured to be controllably positioned to a pushing position in which the tip portion is engaged with the edge of the patterning device and to a disengaged position in which the tip portion is not engaged with the edge of the patterning device.

In an embodiment, a patterning device transport system for use in holding and moving a patterning device in a lithographic imaging apparatus includes a patterning device holder, including a chuck configured to releasably hold and support the patterning device. An actuator is configured to apply a holding force to an edge of the patterning device held and supported by the patterning device holder, the holding force being opposed to an inertial force on the patterning device when the patterning device holder is accelerated. The actuator includes a long-stroke actuator portion comprising a linear eccentric drive and a short-stroke actuator portion, connected to the long-stroke actuator portion, and a tip portion, wherein the tip portion is configured to apply the holding force to the edge of the patterning device, the long-stroke actuator portion has a longer travel stroke than a travel stroke of the short-stroke actuator portion and the short-stroke actuator portion has a greater degree of precision than a degree of precision of the long-stroke actuator portion, and the actuator is mounted such that the tip portion of the actuator may be controllably movable by the long-stroke actuator towards and away from the edge of the patterning device such that the tip is positionable to be in a pushing position where the tip portion is engaged with the edge of the patterning device, and to be in a disengaged position where the tip portion is not engaged with the edge of the patterning device.

In an embodiment, a photolithographic system is configured to perform a method of operating any of the systems described above.

Furthermore, in an embodiment, there is provided a computer program product comprising a non-transitory computer readable medium having instructions recorded thereon, the instructions when executed by a computer controlling operation of the systems listed above.

### BRIEF DESCRIPTION OF THE DRAWINGS

The accompanying drawings, which are incorporated in and constitute a part of this specification, show certain aspects of the subject matter disclosed herein and, together with the description, help explain some of the principles associated with the disclosed implementations. In the drawings,

FIG. 1 illustrates a block diagram of various subsystems of a lithographic projection apparatus, according to an embodiment.

FIG. 2 is a schematic diagram of a lithographic projection apparatus, according to an embodiment.

FIG. 3 is a diagram illustrating timing of changes in acceleration for a patterning device holder according to an embodiment.

FIG. 4a schematically illustrates a patterning device holder in accordance with an embodiment, and some of the forces due to acceleration on the patterning device.

FIG. 4b is an expanded view of a pusher in accordance with an embodiment.

FIG. 5 is a schematic view of a translation and locking mechanism for a pusher in accordance with an embodiment.

FIG. 6 is a schematic view of a translation and locking mechanism for a pusher in accordance with an embodiment.

FIG. 7 is a schematic side view of the pusher of FIG. 6.

FIG. 8 is a schematic side view of a translation and locking mechanism for a pusher in accordance with an embodiment.

FIG. 9 is a schematic top view of the translation and locking mechanism of FIG. 8.

FIG. 10 is a block diagram of an example computer system, according to an embodiment.

### DETAILED DESCRIPTION

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid-crystal display panels, thin-film magnetic heads, etc. The skilled artisan will appreciate that, in the context of such alternative applications, any use of the terms “reticle”, “wafer” or “die” in this text should be considered as interchangeable with the more general terms “mask”, “substrate” and “target portion”, respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The patterning device can comprise, or can form, one or more design layouts. The design layout can be generated utilizing CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between devices (such as gates, capacitors, etc.) or interconnect lines, so as to ensure that the devices or lines do not interact with one another in an undesirable way. One or more of the design rule limitations may be referred to as “critical dimension” (CD). A critical dimension of a device can be defined as the smallest width of a line or hole or the smallest space between two lines or two holes. Thus, the CD determines the overall size and density of the designed device. Of course, one of the goals in device fabrication is to faithfully reproduce the original design intent on the substrate (via the patterning device).

The term “mask” or “patterning device” as employed in this text may be broadly interpreted as referring to a generic patterning device that can be used to endow an incoming radiation beam with a patterned cross-section, corresponding to a pattern that is to be created in a target portion of the substrate; the term “light valve” can also be used in this context. Besides the classic mask (transmissive or reflective; binary, phase-shifting, hybrid, etc.), examples of other such patterning devices include a programmable mirror array and a programmable LCD array.

An example of a programmable mirror array can be a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic methods.

An example of a programmable LCD array is given in U.S. Pat. No. 5,229,872, which is incorporated herein by reference.

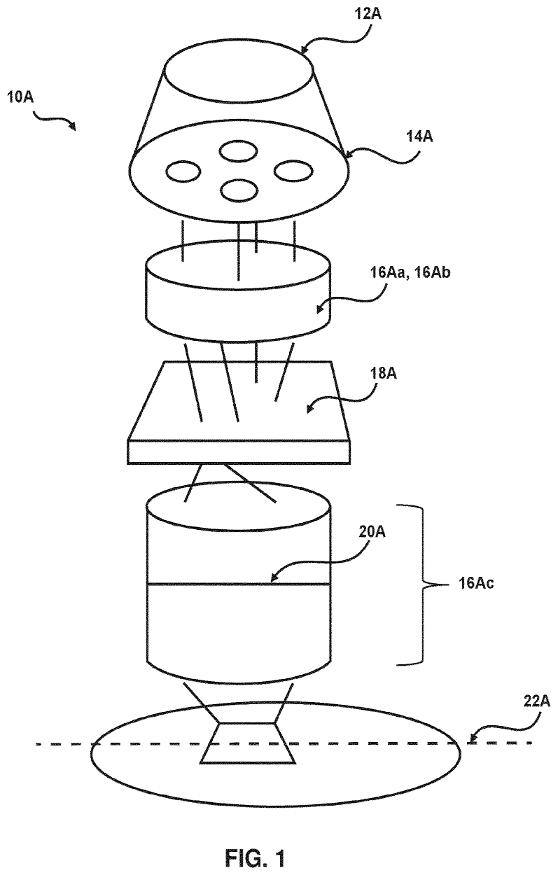

FIG. 1 illustrates a block diagram of various subsystems of a lithographic projection apparatus 10A, according to an embodiment. Major components are a radiation source 12A, which may be a deep-ultraviolet excimer laser source or other type of source including an extreme ultra violet (EUV) source (as discussed above, the lithographic projection apparatus itself need not have the radiation source), illumination optics which, e.g., define the partial coherence (denoted as sigma) and which may include optics 14A, 16Aa and 16Ab that shape radiation from the source 12A; a patterning device (or mask) 18A; and transmission optics 16Ac that project an image of the patterning device pattern onto a substrate plane 22A.

A pupil 20A can be included with transmission optics 16Ac. In some embodiments, there can be one or more pupils before and/or after mask 18A. As described in further detail herein, pupil 20A can provide patterning of the light that ultimately reaches substrate plane 22A. An adjustable filter or aperture at the pupil plane of the projection optics may restrict the range of beam angles that impinge on the substrate plane 22A, where the largest possible angle defines the numerical aperture of the projection optics NA=n sin (Θₘₐₓ), wherein n is the refractive index of the media between the substrate and the last element of the projection optics, and Θₘₐₓ is the largest angle of the beam exiting from the projection optics that can still impinge on the substrate plane 22A.

In a lithographic projection apparatus, a source provides illumination (i.e. radiation) to a patterning device and projection optics direct and shape the illumination, via the patterning device, onto a substrate. The projection optics may include at least some of the components 14A, 16Aa, 16Ab and 16Ac.

The lithographic apparatus may include components collectively called a “wavefront manipulator” that can be used to adjust the shape of a wavefront and intensity distribution and/or phase shift of a radiation beam. In an embodiment, the lithographic apparatus can adjust a wavefront and intensity distribution at any location along an optical path of the lithographic projection apparatus, such as before the patterning device, near a pupil plane, near an image plane, and/or near a focal plane. The wavefront manipulator can be used to correct or compensate for certain distortions of the wavefront and intensity distribution and/or phase shift caused by, for example, the source, the patterning device, temperature variation in the lithographic projection apparatus, thermal expansion of components of the lithographic projection apparatus, etc. Adjusting the wavefront and intensity distribution and/or phase shift can change values of the characteristics represented by the cost function. Such changes can be simulated from a model or actually measured. The design variables can include parameters of the wavefront manipulator.

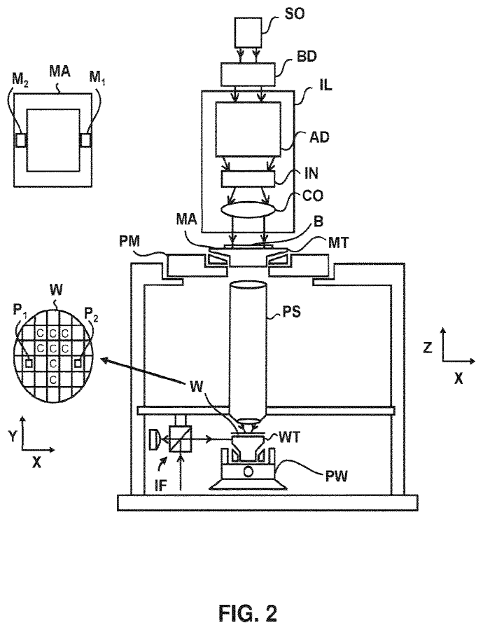

FIG. 2 is a schematic diagram of a lithographic projection apparatus, according to an embodiment.

The lithographic projection apparatus can include an illumination system IL, a first object table MT, a second object table WT, and a projection system PS.

Illumination system IL, can condition a beam B of radiation. In this particular case, the illumination system also comprises a radiation source SO.

First object table (e.g., patterning device table) MT can be provided with a patterning device holder to hold a patterning device MA (e.g., a reticle), and connected to a first positioner to accurately position the patterning device with respect to item PS. The first object table includes a portion that securely holds the patterning device in place during accelerations of the first object table, called a chuck. The chuck may, for example, use vacuum clamping to secure the patterning device MA to the first object table MT.

Second object table (substrate table) WT can be provided with a substrate holder to hold a substrate W (e.g., a resist-coated silicon wafer), and connected to a second positioner to accurately position the substrate with respect to item PS.

Projection system (“lens”) PS (e.g., a refractive, catoptric or catadioptric optical system) can image an irradiated portion of the patterning device MA onto a target portion C (e.g., comprising one or more dies) of the substrate W.

As depicted herein, the apparatus can be of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning apparatuses, such as a beam expander Ex, for example. The illuminator IL may comprise adjusting device AD for setting the outer and/or inner radial extent (commonly referred to as σ-outer and σ-inner, respectively) of the intensity distribution in the beam. In addition, it will generally comprise various other components, such as an integrator IN and a condenser CO. In this way, the beam B impinging on the patterning device MA has a desired uniformity and intensity distribution in its cross-section.

In some embodiments, source SO may be within the housing of the lithographic projection apparatus (as is often the case when source SO is a mercury lamp, for example), but that it may also be remote from the lithographic projection apparatus, the radiation beam that it produces being led into the apparatus (e.g., with the aid of suitable directing mirrors); this latter scenario can be the case when source SO is an excimer laser (e.g., based on KrF, ArF or F2 lasing).

The beam PB can subsequently intercept patterning device MA, which is held on a patterning device table MT. Having traversed patterning device MA, the beam B can pass through the lens PL, which focuses beam B onto target portion C of substrate W. With the aid of the second positioning apparatus (and interferometric measuring apparatus IF), the substrate table WT can be moved accurately, e.g. so as to position different target portions C in the path of beam PB. Similarly, the first positioning apparatus can be used to accurately position patterning device MA with respect to the path of beam B. e.g., after mechanical retrieval of the patterning device MA from a patterning device library, or during a scan. In general, movement of the object tables MT, WT can be realized with the aid of a long-stroke module (coarse positioning) and a short-stroke module (fine positioning). However, in the case of a stepper (as opposed to a step-and-scan tool) patterning device table MT may just be connected to a short stroke actuator, or may be fixed.

The depicted tool can be used in two different modes, step mode and scan mode. In step mode, patterning device table MT is kept essentially stationary, and an entire patterning device image is projected in one go (i.e., a single “flash”) onto a target portion C. Substrate table WT can be shifted in the x and/or y directions so that a different target portion C can be irradiated by beam PB.

In scan mode, essentially the same scenario applies, except that a given target portion C is not exposed in a single “flash.” Instead, patterning device table MT is movable in a given direction (the so-called “scan direction”, e.g., the y direction) with a speed v, so that projection beam B is caused to scan over a patterning device image; concurrently, substrate table WT is simultaneously moved in the same or opposite direction at a speed V=Mv, in which M is the magnification of the lens PL (typically, M=¼ or ⅕). In this manner, a relatively large target portion C can be exposed, without having to compromise on resolution.

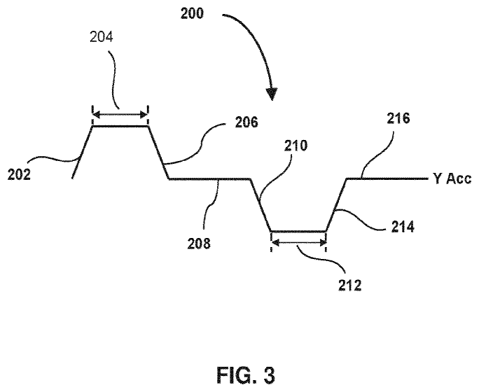

The patterning device table MT in use is scanned at a constant velocity, for example, 4.8 m/s across the field of the projection lens along the scan direction. To achieve these speeds, the patterning device table is accelerated quickly from stationary to high velocity, and at the end of the scan, it is accelerated quickly to zero again before reversing direction to scan in the opposite direction, as illustrated in FIG. 3. The accelerations to achieve these speeds may be as much as 30 g or more. In particular, it is believed that in order to achieve processing speeds of 400 wafers per hour (WPH), the machine may require capabilities of 31 g acceleration.

During constant velocity, there is not any inertial force on the patterning device. During the acceleration and deceleration phases, however, there may be 100 N-150 N of inertial force on a patterning device having a mass of around 0.5 kg. This may lead to the possibility that the patterning device slips relative to the patterning device holder during the periods of high acceleration.

Attempts to solve patterning device slippage include using a chuck that includes a clamp, such as a vacuum system, to hold the patterning device in place and/or using a friction coating to increase friction between the patterning device and the clamp. However, ever increasing production rates demand ever faster direction reversals and, therefore, higher accelerations have reduced the benefits of these solutions. With clamps, the normal force between the patterning device and the clamp generates a friction force during the acceleration and deceleration portions of the scan. The friction force holds the patterning device in place during these portions. However, with vacuum clamps, the friction force is limited by the maximum differential pressure between atmosphere and the vacuum, which now is only about 1 bar. Further, the small surface area of patterning devices in contact with the clamps limits the normal force that can be generated by the clamps. Currently, the highest friction coefficient of suitable friction coatings is only approximately 0.25.

In response, it has been proposed to provide actuators that engage an edge of the patterning device to provide a force counteracting the inertial forces during acceleration stages. Such a system is described, for example, in U.S. Pat. No. 8,885,149, herein incorporated by reference. Though there will be some degree of deformation of the patterning device due to the lateral forces produced by the edge clamping, this is generally minor enough that it does not significantly affect the error budget for imaging (as much as a few tenths of a nanometer at the patterning device level, which translates to less than one tenth of a nanometer at the substrate level).

Returning to FIG. 3, an example of an acceleration timing 200 for a patterning device is illustrated. In a first time period, there is an increasing acceleration phase 202, followed by a steady acceleration period 204, a reducing acceleration phase 206, and a steady travel period 208 (during which imaging would take place). This is followed by a second acceleration 210 (in the opposite direction), a second steady acceleration period 212, and a second reducing acceleration phase 214, followed by a second steady travel period 216.

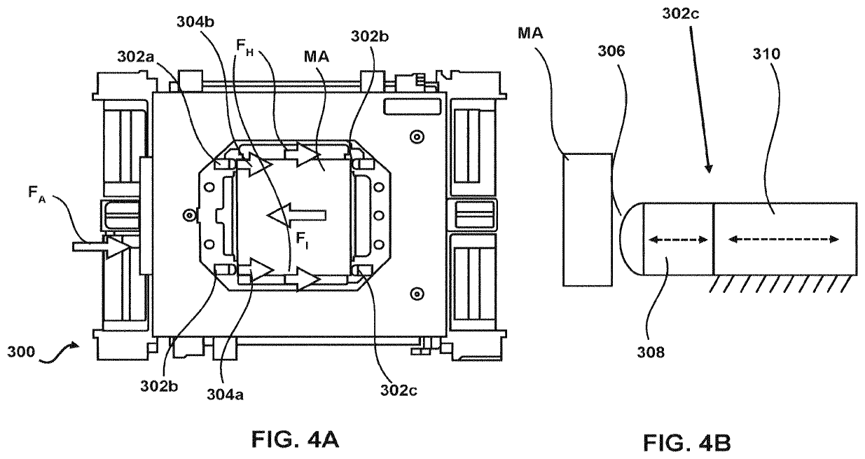

FIG. 4a schematically illustrates a patterning device holder in accordance with an embodiment, and in particular the forces acting on the patterning device MA itself. An inertial force Fr acts in the direction opposite to the direction of acceleration, or scan direction, of the patterning device MA. This force F_{I} is opposed by a force due FA to the chuck's vacuum clamping system. To the extent that there is a difference between the inertial force and the chuck holding force, an additional holding or pushing force F_{H} is required to prevent slippage of the patterning device MA. In the embodiment as shown, this additional pushing force is provided by a set of pushers, 302 a-d, disposed at corners of the chuck. Because the chuck performs rapid scanning movements primarily in a single direction, four inwardly directed pushers 302 a-d are able to provide sufficient stabilizing forces to prevent slippage along the direction of movement of the chuck. Where, as illustrated, the direction of movement is to the right of the figure, the pushers 302a-b will provide respective forces 304a-b opposing F_{I}. When the direction of acceleration is in the opposite direction, the pushers 302c-d will provide the necessary pushing force F_{H}.

FIG. 4b schematically illustrates an example of a pusher 302c in accordance with an embodiment. Though the particular pusher 302c is illustrated, the other pushers 302a, b, d, can be considered to have the same or similar construction.

The pusher 302c is made up of a tip portion 306 that engages an edge of the patterning device MA as it is held by the patterning device holder along with a fine stroke portion 308 that provides movement at high resolution along its axis. For example, the fine stroke portion may be a piezoelectric actuator designed to provide a single degree of freedom along a range of a few microns (e.g., about 10 μm) with a resolution of about 1 nm. Additionally, the pusher 302c is configured to allow for coarse movement (for example by a coarse actuator 310) over a range of a few millimeters (e.g., about 2 mm) with a resolution of about 1 μm. The coarse movement may be obtained in different ways, as will be discussed in greater detail below.

In an embodiment, the pusher 302c further includes a locking mechanism, that is able to hold the actuator in place relative to the patterning device or to be released, allowing the actuator to move freely relative to the patterning device.

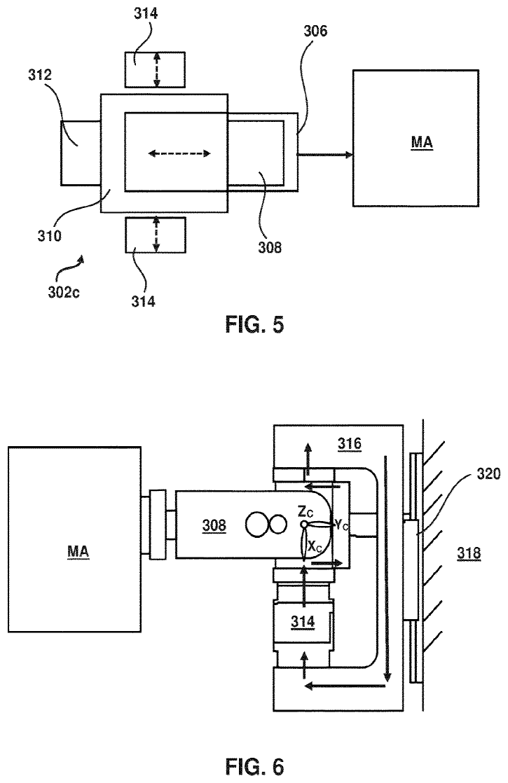

FIG. 5 illustrates a pusher embodiment including a locking mechanism. In the illustrated embodiment, the coarse movement is provided by inertia during an acceleration of the patterning device table MT. The fine stroke portion 308 is mounted slidably on a rail 312, for example, that acts as a linear motion guide, guiding its motion along the axis of movement of the patterning device table MT. When the patterning device MA is moved to the left, for example, the fine stroke portion 308 and its attached tip 306 will undergo relative motion, sliding along the rail 312 so that the tip 306 moves into engagement with an edge of the patterning device. The fine stroke portion 308 may include a piezoelectric actuator. While this is illustrated in the Figure as rightward movement along the arrow, it is in reality a tendency to remain stationary while the patterning device MA is accelerated to the left that causes the engagement between the tip and the edge.

The fine-stroke portion 308 may be configured to include a strain gauge that can provide feedback to a controller of the system to indicate when it is engaged with the edge of the patterning device MA. In this manner, the coarse inertial motion of the tip portion is controllably positioned such that it is engaged, in a pushing position, or disengaged, where the tip is not in contact with the edge of the patterning device. Where the position is not as expected or desired, the controller may initiate a short acceleration outside of the ordinary imaging travel to move the pusher into its appropriate engaged or disengaged position.

In an embodiment, the inertial force approach may be replaced with other devices to provide the coarse positioning. In an example, a linear actuator (voice coil or linear motor), linear screw drive, a piezoelectric actuator, a pneumatic actuator, or a solenoid may be used to perform the coarse positioning.

When the coarse motion has resulted in the tip being positioned as desired, one or more brake members 314 is actuated to clamp the pusher in place to prevent it from traveling along the linear guide. As illustrated, the brakes may include a pair of opposed piezoelectric brake members 314 that provide a force normal to the direction of travel of the coarse and fine actuators. In principle, a single brake member acting on one side may provide the necessary normal force to create sufficient friction between a brake pad included in the brake member and the actuator to prevent movement. Likewise, a static or spring biased member on one side may cooperate with an opposed single brake to provide the normal force.

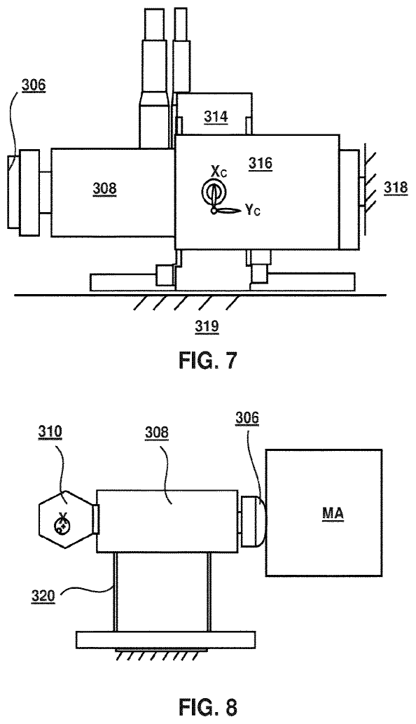

In an embodiment as shown in FIGS. 6 and 7, a single brake member 314 provides the normal force to prevent movement when the pusher is properly positioned. In this embodiment, the piezoelectric brake member 314 extends to apply the normal force. The caliper 316 automatically centers itself as the brake member extends. The caliper may be made from, for example, titanium, titanium alloys, steel, or the like

A linear bearing, or flexure, 320 allows a single degree of freedom for the position of the caliper 316, parallel to a direction of the normal force exerted by the piezoelectric brake member 314. As the brake extends, the caliper 316 self-centers, and the linear bearing 320 allows the caliper to do so without introducing any off-axis moments or rotations about the z-axis. In an embodiment, the linear bearing 320 provides a minimum of about a 20 μm range of motion to the caliper.

The forces generated by the braking operation are largely contained within a loop passing through the caliper 316 and the piezoelectric brake member 314. Thus, these forces do not generate any significant stress on the chuck wall 318 or the chuck floor 319.

In an embodiment, the piezoelectric brake member 314 is retracted when a voltage is applied, and extends when voltage is dropped to zero. That is, motion of the carriage is normally locked, and the carriage is free to move only when a voltage is applied. In the retracted configuration, a gap of about 5-10 μm exists between the brake pads and the carriage, and is divided between the two sides. When extended, this gap is closed.

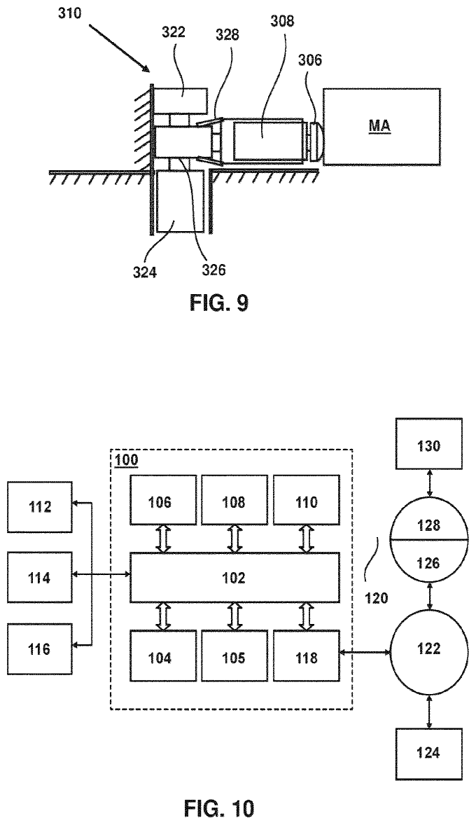

FIGS. 8 and 9 illustrate an alternate device for controlling the coarse position of the pusher tip 306. In this approach, the coarse actuator 310 includes an eccentric drive linear actuator. Motion of the pusher may be constrained, for example, by flexure mounts 320 that act as linear motion guides to allow movement along a single dimension. As will be appreciated, other mounting systems for allowing linear movement could be substituted for the flexure mounts 320. In an embodiment, the eccentric drive linear actuator has an off-axis shaft. The shaft is rotated by the motor 322, within its bearing 324. The motor may be, for example, a servo motor, or a DC brushless motor. The motor may be controlled with an open-loop control, and is selected to have a suitable stall torque. Eccentric drive member 326 is mounted to the shaft in an off-axis relation so that it converts the rotational motion of the shaft into linear motion (of the fine-stroke portion 308, for example) in the manner, for example, of a cam follower. To prevent back drivability of the mechanism the moment due to a force acting on the drive member should be less than a maximum resisting moment due to friction. A gear box or motor brake may be provided for this purpose. As will be appreciated, prevention of back-drive by in this manner will more generally prevent all parasitic (i.e., unintended due to externally applied forces) back or front-drive. As with the inertial embodiment, the piezoelectric fine-stroke portion 308 may include a strain gauge for providing control signals to allow the tip to be correctly positioned relative to the edge of the patterning device.

A set of baffles 328 may be provided to help contain any potential particles generated by motion of the pusher. In an embodiment, the eccentric drive member 326 may comprise a cam. The cam may be magnetically coupled to the carriage on which the fine-stroke portion 308 travels. In this approach, the magnets serve both to allow push and pull of the carriage, and to attract and collect potential ferromagnetic particles that are created due to the friction of the carriage traveling along the rail or guide.

In an embodiment, the tip 306 is made from a material that is generally stiff, but that does not impose too much stress on the edge of the patterning device. By way of example, a material such as a borosilicate glass can provide this balance of properties. In a particular example, N-BK7, available from SCHOTT glass may be used. Because one useful arrangement of the tip includes a convex surface to engage the edge of the patterning device, it is possible to make use of off-the-shelf lens components made from an appropriate glass material.

In the embodiments using electrical actuators, the electrical connections required tend to be of low stiffness compared to, for example, a pneumatic or hydraulic hose.

FIG. 10 is a block diagram that illustrates a computer system 100 which can assist in embodying and/or implementing the pattern selection method disclosed herein. Computer system 100 includes a bus 102 or other communication mechanism for communicating information, and one or more processor(s) 104 (and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment of the invention, portions of the simulation process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In alternative embodiments, hard-wired circuitry may be used in place of or in combination with software instructions to implement the invention. Thus, embodiments of the invention are not limited to any specific combination of hardware circuitry and software.

The term “computer-readable medium” as used herein refers to any medium that participates in providing instructions to processor 104 for execution. Such a medium may take many forms, including but not limited to, non-volatile media, volatile media, and transmission media. Non-volatile media include, for example, optical or magnetic disks, such as storage device 110. Volatile media include dynamic memory, such as main memory 106. Transmission media include coaxial cables, copper wire and fiber optics, including the wires that comprise bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge, a carrier wave as described hereinafter, or any other medium from which a computer can read.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 also preferably includes a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. In accordance with the invention, one such downloaded application provides for the test pattern selection of the embodiment, for example. The received code may be executed by processor 104 as it is received, and/or stored in storage device 110, or other non-volatile storage for later execution. In this manner, computer system 100 may obtain application code in the form of a carrier wave.

The embodiments may further be described using the following clauses:

1. A patterning device transport system for use in holding and moving a patterning device in a lithographic imaging apparatus, comprising:
a patterning device holder, the patterning device holder including a chuck configured to releasably hold and support the patterning device;
an actuator configured to apply a holding force to an edge of the patterning device, the holding force being opposed to an inertial force on the patterning device in response to acceleration of the patterning device holder, the actuator including a fine-stroke portion and a tip portion, wherein the actuator is slidingly mounted on a guide;
a locking mechanism configured to selectively hold the actuator in place relative to the patterning device;
wherein the actuator is configured to controllably position the tip portion to a pushing position in which the tip portion is engaged with the edge of the patterning device and to a disengaged position in which the tip portion is not engaged with the edge of the patterning device; and
wherein the actuator is movable along the guide from the disengaged position to the pushing position.
   2. A patterning device transport system as in clause 1, wherein the locking mechanism comprises at least one piezoelectric brake configured to apply a force on a side of the actuator in a direction substantially perpendicular to a direction of extension of the guide.
   3. A patterning device transport system as in clause 1, wherein the fine-stroke portion includes a strain gauge, and the strain gauge is operable to provide a signal to a controller in response to the tip portion engaging the edge of the patterning device.
   4. A patterning device transport system as in clause 1, wherein the locking mechanism comprises only one piezoelectric brake configured to apply a force on a side of the actuator in a direction substantially perpendicular to a direction of extension of the guide; and
wherein the brake further comprises a floating caliper, the floating caliper configured and arranged to apply the force on the side of the actuator when a piezoelectric element of the piezoelectric brake is actuated.
   5. A patterning device transport system as in clause 4, wherein the piezoelectric element of the piezoelectric brake is in a locked configuration when no voltage is applied to the piezoelectric element.
   6. A patterning device transport system as in clause 4, wherein the floating caliper is mounted on a mount providing a single linear degree of freedom in a direction parallel to a direction of the force applied to the side of the actuator.
   7. A patterning device transport system as in clause 6, wherein the mount is a bearing or a flexure.
   8. A patterning device transport system for use in holding and moving a patterning device in a lithographic imaging apparatus, comprising:
a patterning device holder, the patterning device holder including a chuck configured to releasably hold and support the patterning device;
an actuator configured to apply a holding force to an edge of the patterning device, the holding force being opposed to an inertial force on the patterning device in response to acceleration of the patterning device holder, wherein the actuator comprises:
   a long-stroke actuator portion comprising a linear eccentric drive;
   a brake configured to prevent parasitic forces from moving the long-stroke actuator portion;
   a short-stroke actuator portion, connected to the long-stroke actuator portion; and
   a tip portion, wherein the tip portion is configured to apply the holding force to the edge of the patterning device, the long-stroke actuator portion has a longer travel stroke than a travel stroke of the short-stroke actuator portion and the short-stroke actuator portion has a greater degree of precision than a degree of precision of the long-stroke actuator portion;
wherein the long-stroke actuator portion is configured to controllably move the tip portion towards and away from the edge of the patterning device such that the tip is configured to be controllably positioned to a pushing position in which the tip portion is engaged with the edge of the patterning device and to a disengaged position in which the tip portion is not engaged with the edge of the patterning device.
   9. A patterning device transport system as in clause 8, wherein the long-stroke actuator portion comprises a motor having an off-axis shaft to convert rotational motion to linear motion in cooperation with a linear guide member.
   10. A patterning device transport system as in clause 8, wherein the actuator is mounted on the patterning device holder via a linear motion guide.
   11. A patterning device transport system as in clause 9, wherein the linear motion guide comprises a flexure mount.
   12. A patterning device transport system as in clause 9, wherein the motor is a servo motor or a brushless DC motor.
   13. A patterning device transport system as in clause 1 or 8, wherein the fine-stroke portion comprises a piezoelectric actuator.
   14. A patterning device transport system as in clause 1 or 8, wherein the tip portion has a rounded face on a side that engages the edge of the patterning device.
   15. A patterning device transport system as in clause 1 or 8, wherein the tip portion comprises a material different from a material of the fine-stroke portion.
   16. A patterning device transport system as in clause 15, wherein the tip portion comprises a borosilicate glass material.
   17. A method of controlling a patterning device transport system comprising:
accelerating a patterning device holder in a scan direction to controllably move an actuator from a disengaged position in which a tip portion of the actuator is not in contact with an edge of a patterning device held by the patterning device holder to an engaged position in which the tip portion of the actuator is in contact with the edge of the patterning device;
locking the actuator in position relative to the patterning device in response to inertial movement of the actuator; and
applying a holding force with the actuator on the patterning device in a direction opposed to a direction of acceleration of the patterning device holder.
   18. A method of controlling a patterning device transport system comprising:
coarsely positioning, with a linear eccentric drive, a patterning device holder to controllably move an actuator from a disengaged position in which a tip portion of the actuator is not in contact with an edge of a patterning device held by the patterning device holder to an engaged position in which the tip portion of the actuator is in contact with the edge of the patterning device;
locking the linear electric drive with a brake; and
applying a holding force with the actuator on the patterning device in a direction opposed to a direction of acceleration of the patterning device holder.
   19. A computer program product comprising a non-transitory computer readable medium having machine executable instructions recorded thereon, the instructions when executed controlling the device of any of clauses 1-16 or performing the method of any of clauses 17-19.

As used herein, the term “about,” for example when referring to distances, forces, or other quantities, may be considered to mean within plus or minus 10%. The term “concurrently” or “simultaneously” for example describing something “concurrently occurring” or “concurrently varying” means that two or more things are occurring at approximately, but not necessarily exactly, at the same time. For example, varying a pupil design concurrently with a mask pattern can mean making a small modification to a pupil design, then making a small adjustment to a mask pattern, and then another modification to the pupil design, and so on. However, the present disclosure contemplates that in some parallel processing applications, concurrency can refer to operations occurring at the same time, or having some overlapping in time.

While the concepts disclosed herein may be used for imaging on a substrate such as a silicon wafer, it shall be understood that the disclosed concepts may be used with any type of lithographic imaging systems, e.g., those used for imaging on substrates other than silicon wafers.

The descriptions above are intended to be illustrative, not limiting. Thus, it will be apparent to one skilled in the art that modifications may be made as described without departing from the scope of the claims set out below.

1. A patterning device transport system for use in holding and moving a patterning device in a lithographic imaging apparatus, the patterning device transport system comprising:
a patterning device holder the patterning device holder including a chuck configured to releasably hold and support the patterning device;
an actuator configured to apply a holding force to an edge of the patterning device, the holding force being opposed to an inertial force on the patterning device in response to acceleration of the patterning device holder, the actuator including a fine-stroke portion and a tip portion, wherein the actuator is slidingly mounted on a guide; and
a locking mechanism configured to selectively hold the actuator in place relative to the patterning device,
wherein the actuator is configured to controllably position the tip portion to a pushing position in which the tip portion is engaged with the edge of the patterning device and to a disengaged position in which the tip portion is not engaged with the edge of the patterning device, and
wherein the actuator and the guide are configured to provide relative movement between the actuator and the guide from the disengaged position to the pushing position.

2. The patterning device transport system as in claim 1, wherein the locking mechanism comprises at least one piezoelectric brake configured to apply a force on a side of the actuator in a direction substantially perpendicular to a direction of extension of the guide.

3. The patterning device transport system as in claim 1, wherein the fine-stroke portion includes a strain gauge, and the strain gauge is operable to provide a signal to a controller in response to the tip portion engaging the edge of the patterning device.

4. The patterning device transport system as in claim 1, wherein the locking mechanism comprises only one piezoelectric brake configured to apply a force on a side of the actuator in a direction substantially perpendicular to a direction of extension of the guide; and
wherein the brake further comprises a floating caliper, the floating caliper configured and arranged to apply the force on the side of the actuator when a piezoelectric element of the piezoelectric brake is actuated.

5. The patterning device transport system as in claim 4, wherein the piezoelectric element of the piezoelectric brake is in a locked configuration when no voltage is applied to the piezoelectric element.

6. The patterning device transport system as in claim 4, wherein the floating caliper is mounted on a mount providing a single linear degree of freedom in a direction parallel to a direction of the force applied to the side of the actuator.

7. The patterning device transport system as in claim 6, wherein the mount is a bearing or a flexure.

8. A patterning device transport system for use in holding and moving a patterning device in a lithographic imaging apparatus, the patterning device transport system comprising:
a patterning device holder including a chuck configured to releasably hold and support the patterning device; and
an actuator configured to apply a holding force to an edge of the patterning device, the holding force being opposed to an inertial force on the patterning device in response to acceleration of the patterning device holder, wherein the actuator comprises:
a long-stroke actuator portion comprising a linear eccentric drive;
a brake configured to prevent parasitic forces from moving the long-stroke actuator portion;
a short-stroke actuator portion connected to the long-stroke actuator portion; and
a tip portion configured to apply the holding force to the edge of the patterning device,
wherein the long-stroke actuator portion has a longer travel stroke than a travel stroke of the short-stroke actuator portion and the short-stroke actuator portion has a greater degree of precision than a degree of precision of the long-stroke actuator portion, and
wherein the long-stroke actuator portion is configured to controllably move the tip portion towards and away from the edge of the patterning device such that the tip is configured to be controllably positioned to a pushing position in which the tip portion is engaged with the edge of the patterning device and to a disengaged position in which the tip portion is not engaged with the edge of the patterning device.

9. The patterning device transport system as in claim 8, wherein the long-stroke actuator portion comprises a motor having an off-axis shaft to convert rotational motion to linear motion in cooperation with a linear guide member.

10. The patterning device transport system as in claim 9, wherein:
the actuator is mounted on the patterning device holder via a linear motion guide;
the linear motion guide comprises a flexure mount; and
the motor is a servo motor or a brushless DC motor.

11. The patterning device transport system as in claim 8, wherein the short-stroke actuator portion comprises a piezoelectric actuator.

12. The patterning device transport system as in claim 8, wherein the tip portion has a rounded face on a side that engages the edge of the patterning device.

13. The patterning device transport system as in claim 8, wherein the tip portion comprises a material different from a material of the short-stroke actuator portion.

14. The patterning device transport system as in claim 13, wherein the tip portion comprises a borosilicate glass material.

15. A method of controlling a patterning device transport system, the method comprising:
accelerating a patterning device holder in a scan direction to controllably provide relative motion between an actuator and a patterning device held by the patterning device holder from a disengaged position in which a tip portion of the actuator is not in contact with an edge of the patterning device to an engaged position in which the tip portion of the actuator is in contact with the edge of the patterning device;
locking the actuator in position relative to the patterning device in response to inertial relative movement of the actuator; and
applying a holding force with the actuator on the patterning device in a direction opposed to a direction of acceleration of the patterning device holder.

16. The method as in claim 15, wherein the locking comprises applying a force on a side of the actuator in a direction substantially perpendicular to a direction of extension of the guide using at least one piezoelectric device.

17. The method as in claim 15, further comprising providing a signal to a controller in response to the tip portion engaging the edge of the patterning device using a strain gauge of the fine-stroke portion.

18. The method as in claim 15, wherein the locking comprises applying a force on a side of the actuator in a direction substantially perpendicular to a direction of extension of the guide using a floating caliper actuated by a piezoelectric element of a piezoelectric brake.

19. The method as in claim 18, wherein the piezoelectric element of the piezoelectric brake is in a locked configuration when no voltage is applied to the piezoelectric element.

20. The method as in claim 18, wherein the floating caliper is mounted on a mount providing a single linear degree of freedom in a direction parallel to a direction of the force applied to the side of the actuator.
